(19) United States
(12) Patent Application Publication
(10) Pub. No.: US 2014/0084234 A1
(43) Pub. Date: Mar. 27, 2014

(54) POST MANUFACTURING STRAIN MANIPULATION IN SEMICONDUCTOR DEVICES

(71) Applicant: APPLE INC., Cupertino, CA (US)

(72) Inventor: Michael R Seningen, Austin, TX (US)

(73) Assignee: APPLE INC., Cupertino, CA (US)

(21) Appl. No.: 13/628,743

(22) Filed: Sep. 27, 2012

(51) Int. Cl. H01L 29/78; H01L 29/82; H01L 21/336; H01L 45/00

(52) U.S. Cl. 257/2; 257/288; 257/295; 438/3; 257/E29.323; 257/E21.409; 257/E45.001; 257/E29.255

(57) ABSTRACT

A semiconductor device includes a channel strain altering material formed over or in the source and drain regions of the device. The channel strain altering material may be used to alter the strain in a channel region of the device after manufacturing of the device (e.g., after the device is formed or during operable use of the device). Changes in one or more of material properties of the channel strain altering material may be used to change the strain in the channel region. Changes in the material properties of the channel strain altering material may change a physical size or structure of the channel strain altering material. The channel strain altering material may include materials such as phase change materials or ferromagnetic materials.

### BACKGROUND

1. Field of the Invention

The present invention relates to semiconductor devices and methods for forming semiconductor devices. More particularly, the invention relates to methods for altering the stress in a semiconductor device channel after formation of the device.

2. Description of Related Art

In recent semiconductor device process technologies, device scaling alone (e.g., reduced device scaling) has not been sufficient to keep up with desired improvements in performance. To improve the dynamic performance of semiconductor devices, transistor engineering has been utilized to induce physical strain into channels of semiconductor devices (e.g., the channel of a MOSFET (metal-oxide-semiconductor field-effect transistor) or CMOS (complementary metal-oxide-semiconductor) transistor device). The increase in dynamic performance, however, comes with a tradeoff in static leakage, which creates an Iₒₙ to I_{off} ratio.

Large SOCs (system-on-chips) with several transistors may have multiple voltages, voltage islands, complicated logic structures, and varying operating modes. These large SOCs may require current process nodes to provide multiple transistor Iₒₙ to I_{off} ratios from which to choose. During the design of these large and complex SOCs, the choice of transistor types used is a trade-off between dynamic performance and static leakage. This choice is typically made during the design construction time (e.g., the design phase or design compilation time) of the SOC and, thus, is a permanent and unalterable choice for the life of the design. Negative assumptions for variables such as, but not limited to, environmentals, operating modes, and voltages have to be made to a priori produce a desired device.

During manufacturing (making) of current PMOS (p-channel metal-oxide-semiconductor) devices, a compressive nitride cap is placed on top of the transistor and the temperature is elevated to lock in a certain physical pressure (e.g., compressive strain) on the channel of the device. The nitride cap may be subsequently removed but the locked compressive strain on the channel may enhance the dynamic performance of the device. A similar process may be used for an NMOS (n-channel metal-oxide-semiconductor) device to lock in tensile strain on the channel, which improves dynamic performance of the NMOS device. In some processes, materials (such as SiGe or SiC particluate (SiCp)) are placed at the ends of the channels to perform similar strain enhancements. These strain enchancements, however, are decided upon during the design phase of the device, are permanent for the life of the device, and are unalterable in the post-manufacturing phase of the device (e.g., during operable use of the device).

In some devices, the fourth terminal (sometimes referred to as the bulk node) of a traditional CMOS transistor may have some capability to change the device characteristics after manufacturing of the device (e.g., during use of the device). For example, the voltage level on the fourth terminal may be changed to some non-supply value to change the device characteristics. The adjustment of this voltage may modulate the effective threshold voltage of the device. Manipulating the bulk voltage requires an independent well. Many processes are single well processes; therefore, for such processes, only one of the n-channel or the p-channel devices (e.g., NMOS or PMOS devices) bulk can be so manipulated and the adjustment can be difficult to perform.

### SUMMARY

In certain embodiments, a semiconductor device includes a channel strain altering material formed over or in the source and drain regions of the device. One or more materials properties of the channel strain altering material may be used to alter strain in a channel region formed between sources and drains in the device. The channel strain altering material may be used to alter strain in the channel region after the device has been formed and during operable use of the device.

In some embodiments, the channel strain altering material includes phase change materials. The phase of the channel strain altering material may be adjusted to alter the strain in the channel region. The phase of the channel strain altering material may change when, for example, the material is subjected to optical radiation or the material is heated to a phase change temperature. The phase of the channel strain altering material may be changed using external components (e.g., an external laser device or external control of a resistive heating element).

In some embodiments, the channel strain altering material includes ferromagnetic materials. A ferromagnetic property of the channel strain altering material may be adjusted to alter the strain in the channel region. The ferromagnetic property may change when the material is subjected to a magnetic field (e.g., an electromagnetic field). The magnetic field may be generated using, for example, a conductive material in or near the device that generates a magnetic field when a current is provided to the conductive material.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIG. 1A depicts a side view representation of an embodiment of a gate formed over a source and a drain.

FIG. 1B depicts a top view representation of the gate and the source and the drain of FIG. 1A.

FIG. 2 depicts a side-view representation of an embodiment of a semiconductor device with strained channel regions.

FIGS. 3A and 3B depict representations of strain in a channel region before (FIG. 3A) and after (FIG. 3B) gate material is removed from above the channel.

FIG. 4 depicts a side-view representation of an embodiment of a semiconductor device with channel strain altering material formed over the source and drain regions.

FIG. 5 depicts a side-view representation of an embodiment of a semiconductor device with a heat generating material formed adjacent to channel strain altering material.

FIG. 6 depicts a side-view representation of an embodiment of a semiconductor device with channel strain altering material being ferromagnetic material.

FIG. 7 depicts a side-view representation of an embodiment of a semiconductor device with channel strain altering material substantially covering the gates.

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DETAILED DESCRIPTION OF EMBODIMENTS

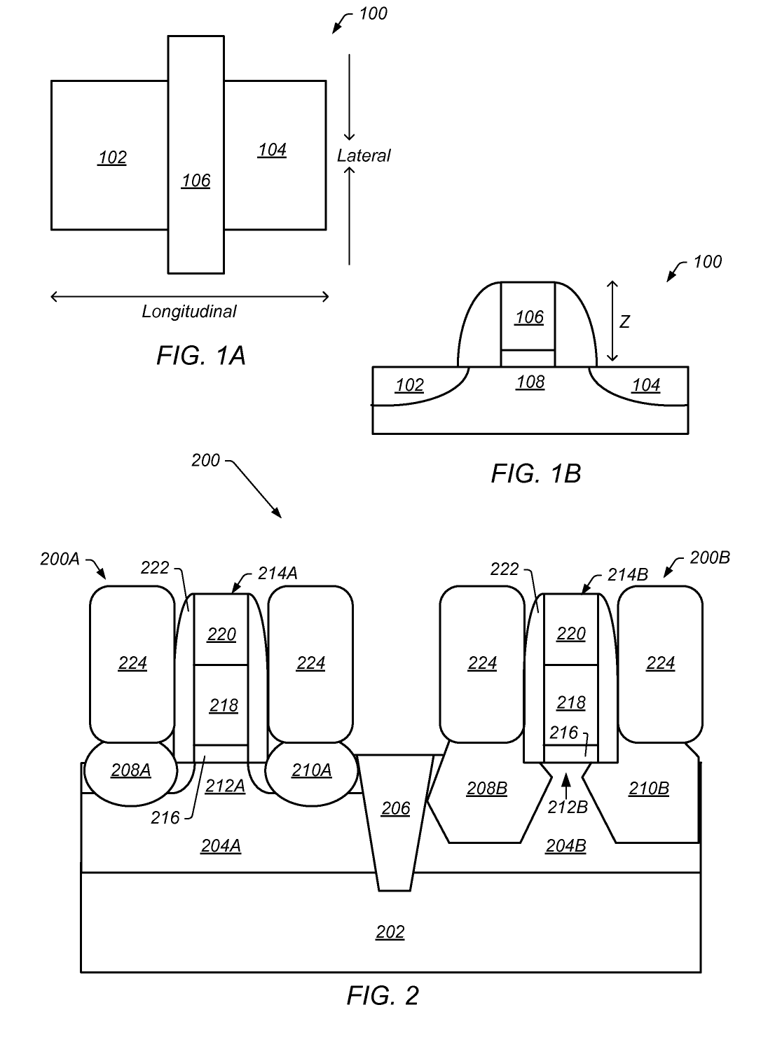

FIG. 1A depicts a side view representation of an embodiment of a gate formed over a source and a drain. FIG. 1B depicts a top view representation of the gate and the source and the drain. Device 100 includes source 102 and drain 104 may be formed in a semiconductor substrate (not shown). Gate 106 on the semiconductor substrate with channel 108 formed under the gate and between source 102 and drain 104. Conduction in a semiconductor device with source 102, drain 104, and gate 106 is proportional to mobility in the device. Average drift mobility in device 100 may be given by EQN. 1:

$$μ = \frac{q}{{m}^{*}} \overline{τ} ; \qquad ( 1 )$$

where μ is average drift mobility, q is elementary charge, m* is effective mass, and τ̅ is average scattering time.

Based on EQN. 1, strain in channel 108 may improve conduction by reducing scattering and/or reducing effective mass. Reducing scattering may warp or shift energy bands to reduce the number of places carriers can go. Reducing effective mass may move the carriers to places where the effective mass is lower and/or warp the energy bands to make the effective mass lower where the carriers are located.

The type of stress that improves conduction may vary depending on the nature (e.g., channel doping) of channel 108 and/or the direction of the channel strain. Typically, tensile strain improves conduction in n-channel devices (e.g., NMOS devices) and compressive strain improves conduction in p-channel devices (e.g., PMOS devices). The direction of the channel strain may, however, also alter how the strain affects the conduction in the devices. As shown in FIGS. 1A and 1B, strain can be longitudinal (X), lateral (Y), or depth (Z) directions. TABLE 1 summarizes the effects of tensile or compressive strain on either NMOS or PMOS devices.

TABLE 1

| Direction of Strain | NMOS | PMOS |
|---|---|---|
| Longitudinal (X) | Tensile | Compressive |
| Lateral (Y) | Tensile | Tensile |
| Depth (Z) | Compressive | Tensile |

FIG. 2 depicts a side-view representation of an embodiment of a semiconductor device with strained channel regions. Device 200 includes NMOS device 200A and PMOS device 200B formed on substrate 202. Substrate 202 may be, for example, a silicon substrate. NMOS device 200A is formed over p-well region 204A and PMOS device 200B is formed over n-well region 204B. P-well region 204A and n-well region 204B are separated by isolation region 206. Source 208A and drain 210A are formed in p-well region 204A while source 208B and drain 210B are formed in n-well region 204B. Channel region 212A is formed between source 208A and drain 210A in NMOS device 200A. Channel region 212B is formed between source 208B and drain 210B in PMOS device 200B.

In certain embodiments, NMOS device 200A includes gate 214A formed over channel region 212A and PMOS device 200B includes gate 214B formed over channel region 212B. Each gate 214A, 214B may include gate oxide 216, gate conductive layer 218, hard mask 220, and gate spacers 222. Gate oxide 216 may be, for example, silicon oxide, silicon nitride, silicon oxynitride, and/or a high-k dielectric material. Gate conductive layer 218 may be, for example, polysilicon or metal. Hard mask 220 and gate spacers 222 may be, for example, silicon oxide, silicon nitride, or silicon oxynitride.

In certain embodiments, etch stop layers 224 are formed on the sides of gates 214A, 214B and above sources 208A, 208B and drains 210A, 210B. In some embodiments, etch stop layers 224 are formed coplanar with gates 214A, 214B. In some embodiments, etch stop layers 224 are formed over gates 214A, 214B (e.g., the etch stop layers are formed as caps that cover the sides and the top of the gates). Etch stop layers 224 may be tensile etch stop layers including, for example, tensile silicon nitride layers.

In certain embodiments, source 208A and drain 210A in NMOS device 200A include SiCp or another material that, in combination with etch stop layers 224, induce tensile strain in channel region 212A. Complementarily, source 208B and drain 210B may include SiGe or another material that, in combination with etch stop layers 224, induces compressive strain in channel region 212B. Thus, SiCp and/or SiGe may be used as strain-inducing layers. As shown in FIG. 2, silicon in channel regions 212A, 212B may be placed under tensile strain or compressive strain due to the presence of different materials on opposing sides of the channel region. The amount of strain in channel regions 212A, 212B, however, is determined during the design phase of device 200 and the amount of strain is locked in once the device is formed (e.g., manufactured).

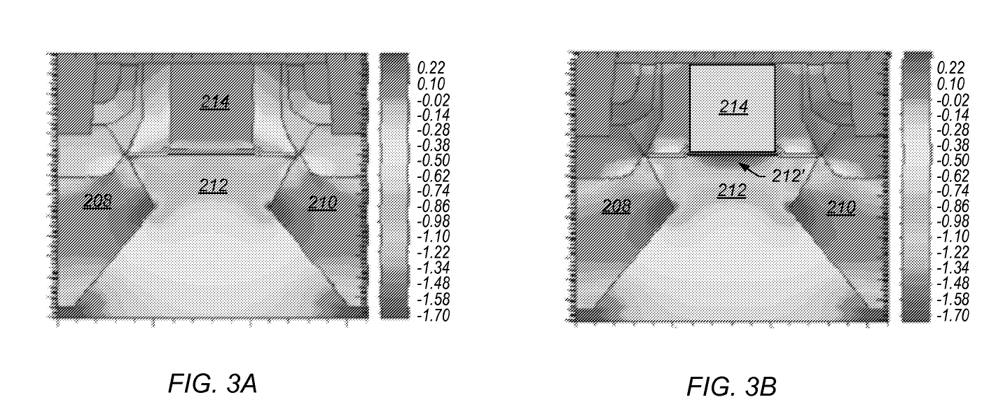

FIGS. 3A and 3B depict representations of strain in a channel region before (FIG. 3A) and after (FIG. 3B) gate material is removed from above the channel. The shading and relative numbers on the shading key in FIGS. 3A and 3B present the relative amounts of strain in the device with positive numbers representing tensile strain and negative numbers representing compressive strain. In FIG. 3A, gate 214 is present above channel region 212 between source 208 and drain 210. The shading in FIG. 3A shows that there is some compressive strain in channel region 212. This slight compressive strain, however, may produce a less than optimal drive current from the device.

In FIG. 3B, the material in gate 214 has been removed from above channel region 208 between source 208 and drain 210. The removal of the gate material significantly increases the compressive strain in channel region 212, as shown by dark region 212′ in the channel region. This higher compressive strain in channel region 212 produces a much higher drive current in the device. The differences in the strain shown in FIGS. 3A and 3B illustrates how the presence or absence of material can affect strain in channel region 208 and, thus, the drive current produced from the device. FIG. 3B depicts how the removal of a material can affect strain in channel region 212. A change in a material's physical structure and/or footprint (size), however, may also affect strain in channel region 212. For example, a material that changes structure or size as it changes phase (e.g., a phase change material) or a material that changes properties in the presence of a magnetic field (e.g., a ferromagnetic material) may be used to change the strain in the channel region during operation (operable use) of the device.

Phase change materials and ferromagnetic materials have previously been used in advanced memory devices (e.g., non-volatile memory (RAM) devices). In RAM devices with phase change materials (e.g., PRAMs), the phase change material (such as chalcogenide glass) switches between crystalline and amorphous phases with changes in temperature of the material. The temperature of the material may be controlled by controlling heat applied to the material. For example, heat may be produced by the passage of an electric current through the material itself or an adjacent material. The produced heat may increase the temperature of the phase change material while turning off the produced heat will allow the phase change material to cool (decrease in temperature).

In RAM devices with ferromagnetic materials (e.g., MRAMs), an external magnetic field is used to change the magnetic field of a ferrogmagnetic material in the device. The change in the magnetic field changes the ferrogmagnetic material's resistance without any change in physical structure or shape. It may be possible, however, to provide a ferromagnetic material that changes physically in structure or shape with the use of an external magnetic field.

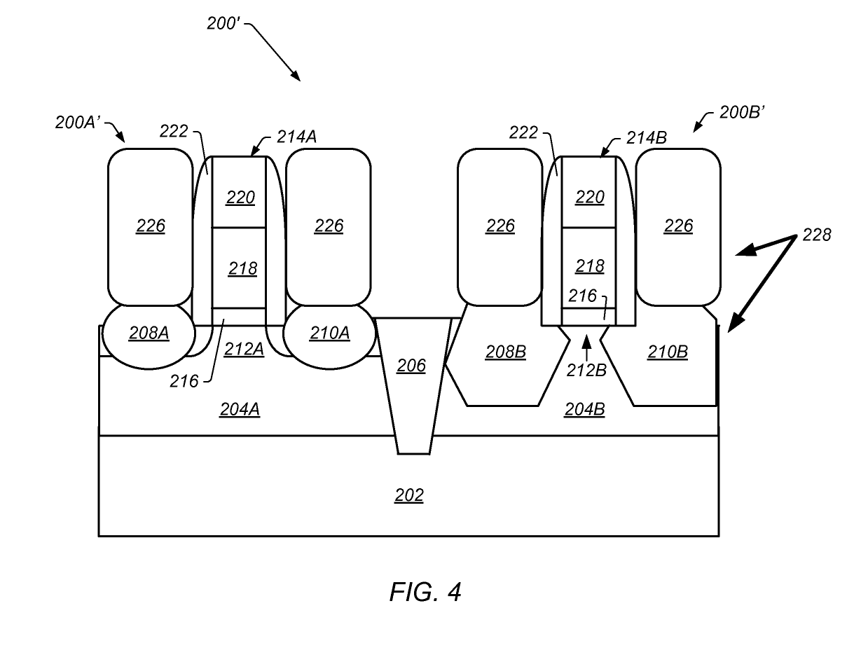

FIG. 4 depicts a side-view representation of an embodiment of a semiconductor device with channel strain altering material formed over the source and drain regions. Device 200′ includes NMOS device 200A′ and PMOS device 200B′, which are substantially similar to NMOS device 200A and PMOS device 200B depicted in FIG. 2 except etch stop layers 224 are replaced with channel strain altering material 226. In certain embodiments, as shown in FIG. 4, at least part of channel strain altering material 226 contacts source regions 208A, 208B and drain regions 210A, 210B. In some embodiments, channel strain altering material 226 may be formed in source regions 208A, 208B and drain regions 210A, 210B (e.g., the channel strain altering material is added to or formed as part of the source and drain regions). In some embodiments, channel strain altering material 226 may be formed over or in either source regions 208A, 208B or drain regions 210A, 210B (e.g., the channel strain altering material is formed over or in only the source regions or only the drain regions).

In certain embodiments, channel strain altering material 226 is a material that has one or more material properties that can be changed (adjusted). Adjustment of the one or more material properties of channel strain altering material 226 may alter strain in channel region 212A and/or channel region 212B. For example, adjustment of a material property of channel strain altering material 226 may physically change the structure or shape of the channel strain altering material, which alters the strain in channel region 212A and/or channel region 212B. In certain embodiments, channel strain altering material 226 is used to increase tensile strain in channel region 212A (e.g., the channel region of NMOS device 200A′) and/or increase compressive strain in channel region 212B (e.g., the channel region of PMOS device 200B′). Increasing the strain (tensile or compressive) in channel region 212A and/or channel region 212B may improve the performance of device 200′.

In some embodiments, channel strain altering material 226 is a phase change material. For example, channel strain altering material 226 may alter form from amorphous to crystalline, or vice versa, to alter the strain in channel region 212A and/or channel region 212B. The switch between phases of the material (e.g., the switch from amorphous to crystalline) may alter the structure or shape of channel strain altering material 226. For example, channel strain altering material 226 may increase in size when switching phases. The change in structure or shape may then increase or decrease strain in channel region 212A and/or channel region 212B. Thus, external control of the phase of channel strain altering material 226 (e.g., the phase change material) may be used to control the strain in channel region 212A and/or channel region 212B.

In one embodiment, the phase of channel strain altering material 226 is controlled using optical radiation. For example, as shown in FIG. 4, optical radiation 228 may be incident on channel strain altering material 226 with the channel strain altering material being either above source regions 208A, 208B and drain regions 210A, 210B or in the source and drain regions. Optical radiation 228 may, for example, be laser radiation incident on channel strain altering material 226. Optical radiation 228 may be provided by, for example, a laser emitting device formed on substrate 202 or an external laser emitting device (e.g., a laser device similar to those used in programmable optical storage devices). When optical radiation 228 strikes (is incident on) channel strain altering material 226, the optical radiation may induce a phase change in the channel strain altering material (e.g., the phase change material) and alter strain in channel region 212A and/or channel region 212B. Thus, optical radiation 228 may be used to control the strain in channel region 212A and/or channel region 212B.

In another embodiment, the phase of channel strain altering material 226 is controlled by controlling the temperature of the channel strain altering material. The phase of channel strain altering material 226 may change with temperature. For example, channel strain altering material 226 may change from an amorphous phase to a crystalline phase with increasing temperature (e.g., as the temperature increases above a phase change temperature of the material). Thus, when channel strain altering material 226 is heated to a desired temperature, the phase of the channel strain altering material changes and the strain in channel region 212A and/or channel region 212B is altered.

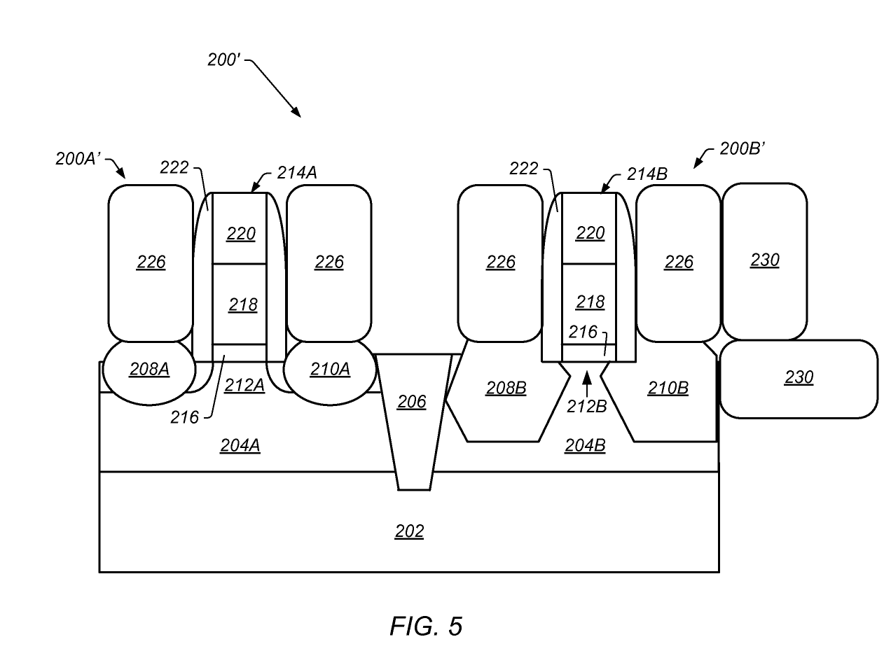

FIG. 5 depicts a side-view representation of an embodiment of a semiconductor device with a heat generating material formed adjacent to channel strain altering material 226. Heat generating material 230 element may be located adjacent or near channel strain altering material 226. Heat generating material 230 may be adjacent or near source regions 208A, 208B and drain regions 210A, 210B when channel strain altering material 226 is in the source and drain regions. Heat generating material 230 may be a resistive heating element or another suitable heating element that generates heat to increase the temperature of channel strain altering material 226. Heat generated by heat generating material 230 may be controlled (e.g., by controlling the current applied to the resistive heating element) to controllably increase the temperature of channel strain altering material 226 to the desired temperature (e.g., the phase changing temperature). Thus, controllable heating of heat generating material 230 may be used to control changes in the strain in channel region 212A and/or channel region 212B.

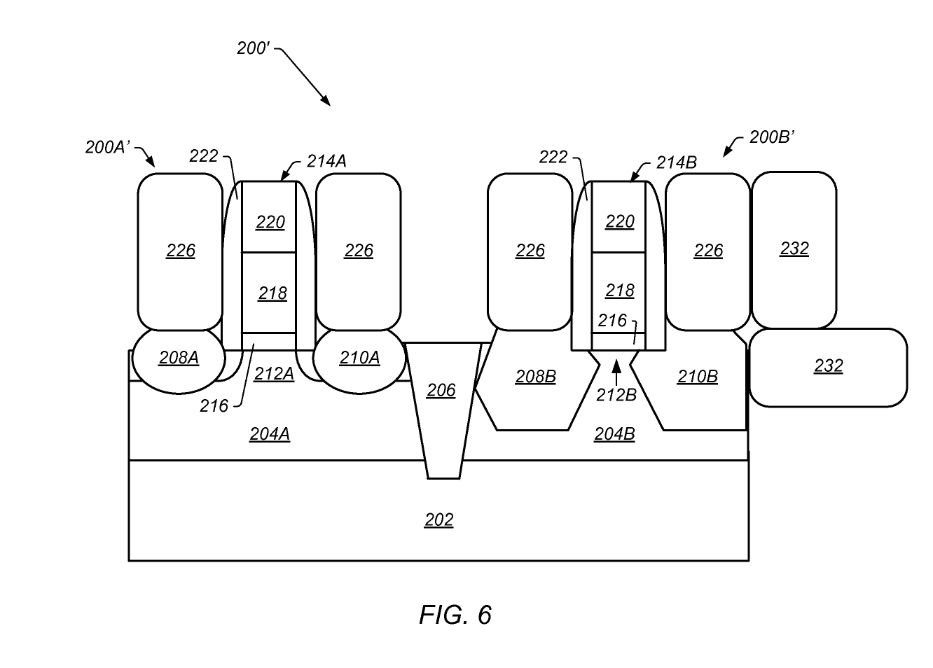

In some embodiments, channel strain altering material 226 is a ferromagnetic material or includes ferromagnetic material. FIG. 6 depicts a side-view representation of an embodiment of a semiconductor device with channel strain altering material 226 being ferromagnetic material. In such embodiments, adjustment of a ferromagnetic property of channel strain altering material 226 alters strain in channel region 212A and/or channel region 212B. For example, a magnetic orientation of the ferromagnetic material (e.g., channel strain altering material 226) may change in the presence of a magnetic field. This change in the magnetic orientation may alter the physical size or shape of channel strain altering material 226. For example, the change in magnetic orientation may increase a horizontal width and decrease a vertical height of channel strain altering material 226. Such a change may increase strain in channel region 212A and/or channel region 212B.

In some embodiments, as shown in FIG. 6, conductive material 232 may be located adjacent or near channel strain altering material 226. Conductive material 232 may be adjacent or near source regions 208A, 208B and drain regions 210A, 210B when channel strain altering material 226 is in the source and drain regions. Conductive material 232 may be used to produce a magnetic field (e.g., an electromagnetic field) that affects ferromagnetic material in channel strain altering material 226. Thus, conductive material 232 may be used to adjust the ferromagnetic property of channel strain altering material 226 (e.g., change the orientation of the channel strain altering material) and alter strain in channel region 212A and/or channel region 212B.

Conductive material 232 may generate the magnetic field, for example, when a current is provided to the conductive material. The magnetic field (e.g., electromagnetic field) produced by conductive material 232 may thus be controlled by controlling the current provided to the conductive material. Controlling the magnetic field produced by conductive material 232 then allows for control of the change in the ferromagnetic property of channel strain altering material 226 and the change in strain in channel region 212A and/or channel region 212B.

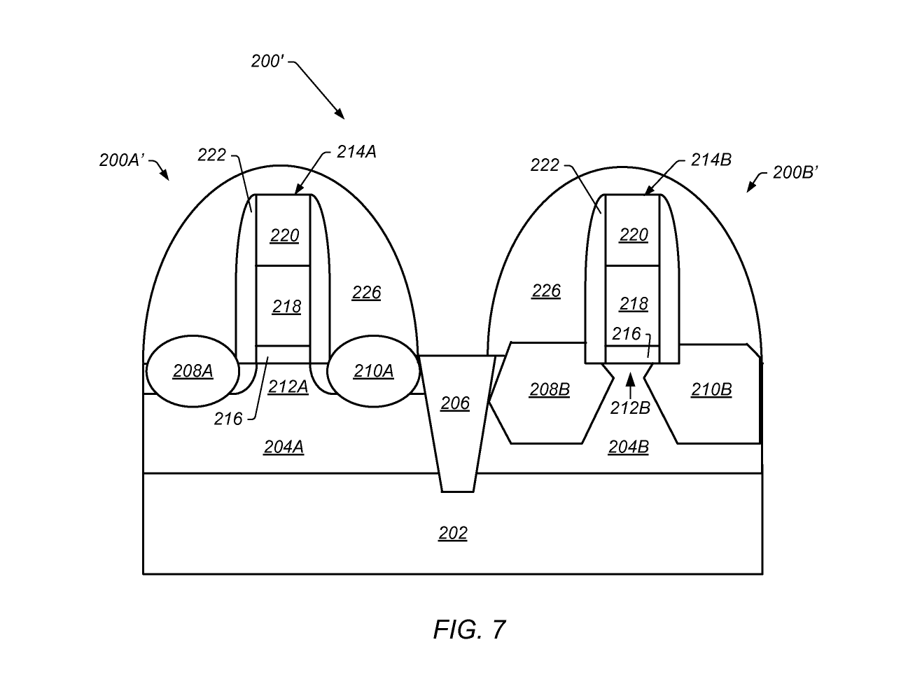

In certain embodiments, as shown in FIGS. 4-6, channel strain altering material 226 is formed coplanar with gates 214A, 214B. Channel strain altering material 226 may, however, be formed in all dimensions in and around gates 214A, 214B. For example, channel strain altering material 226 may be formed over gates 214A, 214B such that the channel strain altering material at least partially cover gates 214A, 214B or substantially cover the gates. FIG. 7 depicts a side-view representation of an embodiment of a semiconductor device with channel strain altering material 226 substantially covering gates 214A, 214B (e.g., the channel strain altering material is formed as a cap that cover the sides and the top of the gates (substantially encloses the gates on the surface of substrate 202)).

For the embodiments described above in FIGS. 4-6, changes in the strain in channel region 212A and/or channel region 212B induced by changes in channel strain altering material 226 (e.g., phase changes or ferromagnetic changes) may be controlled such that the changes only occur when desired. For example, the changes may only occur when the control method is enabled (e.g., optical radiation, resistive heating, or magnetic field). In certain embodiments, the change in the strain in channel region 212A and/or channel region 212B is relative to the amount of change produced by the control method.

In certain embodiments, the original strain in channel region 212A and/or channel region 212B (e.g., the strain after formation of the device and before any change in channel strain altering material 226) may be preserved in the absence of any control method (e.g., optical radiation, resistive heating, or magnetic field) being applied to the device. For example, the strain in channel region 212A and/or channel region 212B may return to the original strain after the control method is turned off (e.g., the optical radiation, the resistive heating, or the magnetic field are turned off). In some embodiments, the original strain in channel region 212A and/or channel region 212B is by further changes applied by the control method (e.g., different optical radiation, further heating, or a different magnetic field). In some embodiments, the altered strain in channel region 212A and/or channel region 212B is maintained for an extended period of time in the absence of any applied control method (e.g., the absence of optical radiation, heating, or magnetic field). The extended period of time may be determined by, for example, the time needed for properties of channel strain altering material 226 to return to their original behavior.

Devices using channel strain altering material 226, such as those described in the embodiments depicted in FIGS. 4-6, may allow for the ability to change design characteristics of the device “on the fly” (e.g., post-process corrections at any time after the device has been manufactured or during operable use of the device such as use of the device in a consumer product). These devices may have improved programmibility and enhanced capabilities for functional control. Channel strain altering material 226 may be used to alter the strain in channel region 212A and/or channel region 212B to counteract or compensate for a variety of post-manufacturing issues. For example, channel strain altering material 226 may be used to counteract the effects of NBTI (negative bias temperature instability) or HCI (hot carrier injection) as the device ages or compensate for temperature inversion effects or extreme IR drops.

Devices using channel strain altering material 226 may also be switched between high performance (but high leakage) operating states and low performance (low leakage) operating states. High performance operating states may be desired when static leakage is not an issue while low performance operating states may be desired at other times such as during sleep modes. The tunability in the leakage state of the device may used in a variety of situations (e.g., manufacturing adjustment, product binning, extended/deeper sleep modes, or intensive bursts of performance needs).

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A semiconductor device, comprising:
a semiconductor substrate;
source and drain regions formed in the semiconductor substrate;
a channel region formed in the semiconductor substrate between the source and drain regions;
a gate formed over the channel region; and
a channel strain altering material formed on at least one side of the channel region;
wherein adjustment of one or more material properties of the channel strain altering material alters strain in the channel region.

2. The device of claim 1, wherein at least part of the channel strain altering material contacts at least one of the source region and the drain region.

3. The device of claim 1, wherein the channel strain altering material is formed over at least one of the source region and the drain region.

4. The device of claim 1, wherein the channel strain altering material is formed in at least one of the source region and the drain region.

5. The device of claim 1, wherein adjustment of one or more material properties of the channel strain altering material to alter strain in the channel region takes place during operable use of the device.

6. The device of claim 1, wherein the channel strain altering material is coplanar with the gate.

7. The device of claim 1, wherein the channel strain altering material at least partially covers an upper surface of the gate.

8. A semiconductor device, comprising:
a semiconductor substrate;
source and drain regions formed in the semiconductor substrate;
a channel region formed in the semiconductor substrate between the source and drain regions with opposing sides of the channel region contacting the source and drain regions;
a gate formed over the channel region; and
a phase change material formed on at least one side of the channel region;
wherein adjustment of a phase of the phase change material alters strain in the channel region.

9. The device of claim 8, wherein the phase of the phase change material changes when the phase change material is subjected to optical radiation.

10. The device of claim 8, wherein the phase of the phase change material changes with temperature.

11. The device of claim 10, further comprising a heat generating material formed on the semiconductor substrate, wherein the heat generating material is controllable to controllably increase a temperature of the phase change material.

12. A semiconductor device, comprising:
a semiconductor substrate;
source and drain regions formed in the semiconductor substrate;
a channel region formed in the semiconductor substrate between the source and drain regions with opposing sides of the channel region contacting the source and drain regions;
a gate formed over the channel region; and
a ferromagnetic material formed on at least one side of the channel region;
wherein adjustment of a ferromagnetic property of the ferromagnetic material alters strain in the channel region.

13. The device of claim 12, wherein the ferromagnetic property of the ferromagnetic material changes in a presence of a magnetic field in the semiconductor device.

14. The device of claim 12, wherein the ferromagnetic property comprises a magnetic orientation in the ferromagnetic material.

15. The device of claim 12, further comprising a conductive material formed on the semiconductor substrate, wherein the conductive material is controllable to produce a magnetic field that alters the ferromagnetic property of the ferromagnetic material.

16. A method for forming a semiconductor device, comprising:
forming source and drain regions in a semiconductor substrate;
forming a channel region in the semiconductor substrate between the source and drain regions;
forming a gate over the channel region; and
forming a channel strain altering material on at least one side of the channel region, wherein adjustment of one or more material properties of the channel strain altering material alters strain in the channel region during use of the semiconductor device.

17. The method of claim 16, further comprising forming the channel strain altering material over at least one of the source region and the drain region.

18. The method of claim 16, further comprising forming the channel strain altering material in at least one of the source region and the drain region.

19. The method of claim 16, further comprising forming a heat generating material on the semiconductor substrate, wherein the heat generating material is controllable to controllably increase a temperature of the channel strain altering material.

20. The method of claim 16, further comprising forming a conductive material on the semiconductor substrate, wherein the conductive material is controllable to produce a magnetic field that alters a ferromagnetic property of the channel strain altering material.

21. A method for altering strain in a semiconductor device, comprising:
altering strain in a channel region of a semiconductor device by altering a material property of a channel strain altering material near the channel region, wherein the semiconductor device comprises:
a semiconductor substrate;
source and drain regions formed in the semiconductor substrate;
the channel region formed in the semiconductor substrate between the source and drain regions with opposing sides of the channel region contacting the source and drain regions;
a gate formed over the channel region; and
the channel strain altering material formed on at least one side of the channel region.

22. The method of claim 21, further comprising altering strain in the channel region of the semiconductor device by altering a phase of the channel strain altering material.

23. The method of claim 21, further comprising altering strain in the channel region of the semiconductor device by altering a magnetic orientation of the channel strain altering material.

24. The method of claim 21, further comprising increasing tensile strain in the channel region by altering the material property of the channel strain altering material near the channel region.

25. The method of claim 21, further comprising increasing compressive strain in the channel region by altering the material property of the channel strain altering material near the channel region.
